(19) United States
(12) Patent Application Publication
(10) Pub. No.: US 2024/0222254 A1
(43) Pub. Date: Jul. 4, 2024

(54) ELECTRONIC APPARATUS

(71) Applicant: SHINKO ELECTRIC INDUSTRIES CO., LTD., Nagano-shi (JP)

(72) Inventors: Kenichi Koi, Nagano (JP); Takumi Yumoto, Nagano (JP); Yoichi Nishihara, Nagano (JP)

(21) Appl. No.: 18/539,797

(22) Filed: Dec. 14, 2023

(30) Foreign Application Priority Data
Dec. 28, 2022 (JP) 2022-211874

(51) Int. Cl. H01L 23/498; H01L 23/00; H01L 23/12; H01L 23/31; H01L 25/065

(52) U.S. Cl. CPC H01L 23/49844; H01L 23/12; H01L 23/3121; H01L 24/32; H01L 24/33; H01L 25/0655; H01L 2224/32225; H01L 2224/33181; H01L 2924/1203; H01L 2924/13055; H01L 2924/13091; H01L 2924/181

(57) ABSTRACT

An electronic apparatus includes a lead frame, a wiring board, and a sealing resin. The wiring board mounts an electronic component boded to the lead frame. The sealing resin seals the lead frame, the electronic component, and the wiring board. The lead frame includes a first surface bonded to the electronic component and a second surface located opposite to the first surface and exposed from the sealing resin. The wiring board includes an insulating base material, a wiring layer formed on a first surface of the insulating base material, and an adhesive layer laminated on a second surface of the insulating base material on an opposite side of the first surface and including a second surface to which the electronic component is bonded. The first surface of the insulating base material and the second surface of the adhesive layer are covered by the sealing resin.

### CROSS-REFERENCE TO RELATED APPLICATION

This application is based upon and claims the benefit of priority of the prior Japanese Patent Application No. 2022-211874, filed on Dec. 28, 2022, the entire contents of which are incorporated herein by reference.

### FIELD

The embodiment discussed herein is related to an electronic apparatus.

### BACKGROUND

In recent years, an electronic apparatus in which a lead frame that is made of metal is bonded to an electronic component, such as a semiconductor element, that is mounted on a substrate, and the lead frame and the electronic component bonded to the lead frame are sealed with sealing resin is known.

Japanese Laid-open Patent Publication No. 2020-167233

However, in the electronic apparatus in which the lead frame and the electronic component that is bonded to the lead frame are sealed with resin, it is difficult to fully dissipate heat that is generated by the electronic component, which is a problem.

Specifically, peripheries of the lead frame and the electronic component that is bonded to the lead frame are entirely covered by the sealing resin, so that heat generated by the electronic component is dissipated from the lead frame or dissipated from the lead frame through the sealing resin. However, thermal conductivity of the sealing resin is lower than thermal conductivity of the lead frame, so that heat dissipation efficiency is not much high. Therefore, in particular, when heat generation amount of the electronic component is relatively large, it is difficult to fully dissipate heat from the electronic component.

The disclosed technology has been conceived in view of the foregoing situation, and an object of the disclosed technology is to provide an electronic apparatus that is able to improve heat dissipation efficiency.

### SUMMARY

According to an aspect of an embodiment, an electronic apparatus includes a lead frame that is made of metal; a wiring board that mounts an electronic component bonded to the lead frame; and sealing resin that seals the lead frame, the electronic component, and the wiring board, wherein the lead frame includes a first surface that is bonded to the electronic component and that is covered by the sealing resin, and a second surface that is located opposite to the first surface and that is exposed from the sealing resin, the wiring board includes an insulating base material, a wiring layer that is formed on a first surface of the insulating base material, and an adhesive layer that is laminated on a second surface of the insulating base material on an opposite side of the first surface and that includes a second surface to which the electronic component is bonded, and the first surface of the insulating base material and the second surface of the adhesive layer are covered by the sealing resin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic cross-sectional view illustrating a configuration of an electronic apparatus according to one embodiment;

FIG. 2 is a flowchart illustrating an example of the flow of a method of manufacturing the electronic apparatus according to one embodiment;

FIG. 3 is a diagram illustrating a specific example of a heat sink and lead formation process;

FIG. 4 is a diagram illustrating a specific example of a recessed portion formation process;

FIG. 5 is a diagram illustrating a specific example of a lead bending process;

FIG. 6 is a diagram illustrating a specific example of a cutting process;

FIG. 7 is a diagram illustrating a specific example of a component bonding process;

FIG. 8 is a diagram illustrating a specific example of a resin sealing process;

FIG. 9 is a schematic cross-sectional view illustrating a configuration of an electronic apparatus according to a modification of the embodiment;

FIG. 10 is a flowchart illustrating an example of the flow of a method of manufacturing the electronic apparatus according to the modification of the embodiment;

FIG. 11 is a diagram illustrating a specific example of a heat sink and lead formation process;

FIG. 12 is a diagram illustrating a specific example of a recessed portion formation process;

FIG. 13 is a diagram illustrating a specific example of a lead bending process;

FIG. 14 is a diagram illustrating a specific example of a guide pin attachment process;

FIG. 15 is a diagram illustrating a specific example of a cutting process;

FIG. 16 is a diagram illustrating a specific example of a component bonding process; and

FIG. 17 is a diagram illustrating a specific example of a resin sealing process.

### DESCRIPTION OF EMBODIMENT

An embodiment of an electronic apparatus disclosed in the present application will be described in detail below based on the drawings. The disclosed technology is not limited by the embodiment below.

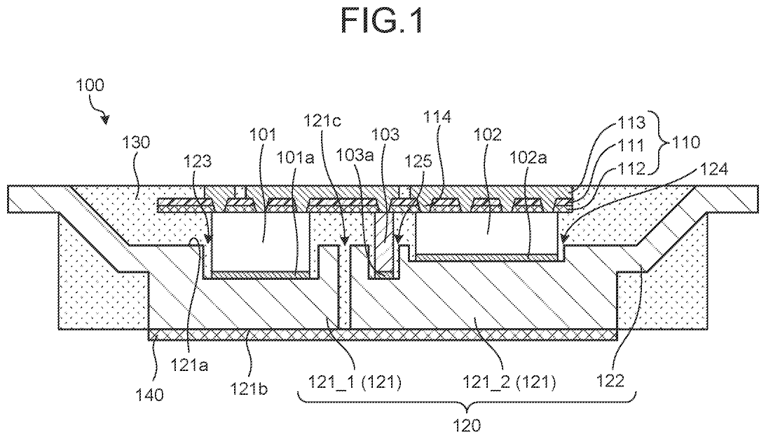

FIG. 1 is a schematic cross-sectional view illustrating a configuration of an electronic apparatus 100 according to one embodiment. Meanwhile, in the following description, a surface that is located at the side of a peripheral component, such as a radiation fin, when the electronic apparatus 100 is mounted on the peripheral component will be referred to as a “lower surface”, a surface located opposite to the peripheral component will be referred to as an “upper surface”, and a vertical direction is defined in accordance with the upper surface and the lower surface. However, the electronic apparatus 100 may be manufactured and used upside down and may be manufactured and used in an arbitrary posture, for example.

The electronic apparatus 100 illustrated in FIG. 1 includes a wiring board 110 and a lead frame 120, and is configured by bonding electronic components 101 and 102 and a conductive member 103 that are mounted on a lower surface of the wiring board 110 to an upper surface of the lead frame 120. Further, the wiring board 110, the lead frame 120, the electronic components 101 and 102, and the conductive member 103 are sealed with sealing resin 130.

The electronic components 101 and 102 are semiconductor elements using, for example, silicon (Si) or silicon carbide (SiC). Further, the electronic components 101 and 102 may be semiconductor elements using gallium nitride (GaN), gallium arsenide (GaAs), or the like. As the electronic components 101 and 102, a semiconductor element as an active component (for example, a silicon chip, such as a central processing unit (CPU)), an Insulated Gate Bipolar Transistor (IGBT), a Metal-Oxide-Semiconductor Field-Effect Transistor (MOSFET), a diode, or the like may be used. The electronic components 101 and 102 have different thicknesses. For example, the thickness of the electronic component 101 is larger than the thickness of the electronic component 102. The thickness of the electronic component 101 may be set to, for example, about 90 micrometers (μm) to 370 μm, and the thickness of the electronic component 102 may be set to, for example, about 70 μm to 350 μm.

The conductive member 103 is, for example, a metal plate, such as a copper (Cu) plate. A thickness of the conductive member 103 is about the same as the thickness of the electronic component 101, and may be set to, for example, about 90 μm to 370 μm.

The sealing resin 130 is, for example, insulating resin, such as thermosetting epoxy resin.

The electronic components 101 and 102 and the conductive member 103 are mounted on the lower surface of the wiring board 110. The wiring board 110 includes an insulating base material 111, an adhesive layer 112, and a wiring layer 113.

The insulating base material 111 is an insulating film-like member and is a base material of the wiring board 110. As a material of the insulating base material 111, for example, insulating resin, such as polyimide resin, polyethylene resin, or epoxy resin, may be used.

The adhesive layer 112 is laminated on a lower surface of the insulating base material 111. The electronic components 101 and 102 and the conductive member 103 are bonded to a lower surface of the adhesive layer 112. As a material of the adhesive layer 112, for example, an adhesive agent of an epoxy type, a polyimide type, a silicone type, or the like may be used. An upper surface of the insulating base material 111 and the lower surface of the adhesive layer 112 are covered by the sealing resin 130. With this configuration, it is possible to improve rigidity of the wiring board 110.

The wiring layer 113 is formed on the upper surface of the insulating base material 111. The wiring layer 113 is electrically connected to the electronic components 101 and 102 and the conductive member 103 via vias 114 that penetrate through the insulating base material 111 and the adhesive layer 112. The wiring layer 113 is connected to the electronic components 101 and 102 and the conductive member 103 via the vias 114, so that the electronic components 101 and 102 and the conductive member 103 are mounted on the lower surface of the wiring board 110. An upper surface of the wiring layer 113 is exposed from the sealing resin 130 at an upper surface of the electronic apparatus 100. With this configuration, it is possible to dissipate, from the upper surface of the wiring layer 113, heat that is transferred from the electronic components 101 and 102 to the wiring layer 113 via the vias 114.

Each of the electronic components 101 and 102 and the conductive member 103 that are mounted on the wiring board 110 is bonded to the lead frame 120.

The lead frame 120 is, for example, a conductive member that is made of metal, such as copper or a copper alloy, and includes a heat sink 121 and a lead 122.

An upper surface 121a of the heat sink 121 is bonded to the electronic components 101 and 102 and the conductive member 103 that are mounted on the wiring board 110. The upper surface 121a of the heat sink 121 is covered by the sealing resin 130, and a lower surface 121b of the heat sink 121 is exposed from the sealing resin 130 at a lower surface of the electronic apparatus 100. Further, the heat sink 121 dissipates, from the lower surface 121b, heat that is transferred from the electronic components 101 and 102 via the upper surface 121a. The heat sink 121 is a part of the lead frame 120 that has high thermal conductivity, and is a plate-like component that is bonded to the electronic components 101 and 102 and that has a relatively large area, so that it is possible to efficiently dissipate heat that is transferred from the upper surface 121a.

Recessed portions are formed on the upper surface 121a of the heat sink 121 at positions corresponding to the electronic components 101 and 102 and the conductive member 103, and the heat sink 121, the electronic components 101 and 102, and the conductive member 103 are bonded at the recessed portions. Specifically, on the upper surface 121a of the heat sink 121, a recessed portion 123 is formed at the position corresponding to the electronic component 101 and the electronic component 101 is housed in the recessed portion 123 and bonded to the bottom surface of the recessed portion 123 via a conductive bonding material 101a, such as solder paste, for example. Further, on the upper surface 121a of the heat sink 121, a recessed portion 124 is formed at the position corresponding to the electronic component 102 and the electronic component 102 is housed in the recessed portion 124 and bonded to the bottom surface of the recessed portion 124 via a conductive bonding material 102a, such as solder paste, for example. Furthermore, on the upper surface 121a of the heat sink 121, a recessed portion 125 is formed at the position corresponding to the conductive member 103 and the conductive member 103 is housed in the recessed portion 125 and bonded to the bottom surface of the recessed portion 125 via a conductive bonding material 103a, such as solder paste, for example. The electronic components 101 and 102 and the conductive member 103 that are mounted on the wiring board 110 are housed in and bonded to the recessed portions 123 to 125 in the heat sink 121, so that it is possible to reduce an interval between the heat sink 121 and the wiring board 110 and reduce the thickness of the electronic apparatus 100. Meanwhile, as the conductive bonding materials 101a, 102a, and 103a, silver (Ag) paste may be used instead of the solder paste.

Bottom surfaces of the recessed portions 123 to 125 are located at different depths from the upper surface 121a of the heat sink 121 in accordance with the respective thicknesses of the electronic components 101 and 102 and the conductive member 103. Specifically, the recessed portions 123 to 125 have certain depths so as to be able to house the electronic components 101 and 102 and the conductive member 103, respectively. With this configuration, the electronic components 101 and 102 and the conductive member 103 are housed in the recessed portions 123 to 125 in an appropriate manner, so that even when the electronic components 101 and 102 and the conductive member 103 have different thicknesses, it is possible to promote reduction of the thickness of the electronic apparatus 100.

The heat sink 121 is divided into a plurality of (two in this example) regions 121_1 and 121_2 that are independent of each other by a slit 121c. The recessed portions 123 to 125 are formed in the regions 121_1 and 121_2 in a distributed manner, and house the corresponding electronic components 101 and 102 and the corresponding conductive member 103. With this configuration, it is possible to independently dissipate heat that is generated by the electronic components 101 and 102 in the regions 121_1 and 121_2.

The lower surface 121b of the heat sink 121 that is exposed from the sealing resin 130 is covered by an adhesive layer 140. When the electronic apparatus 100 is mounted on a peripheral component, such as a radiation fin, the adhesive layer 140 is able to bond the lower surface 121b of the heat sink 121 to the peripheral component. Meanwhile, the adhesive layer 140 may be omitted if necessary.

The lead 122 is connected to a side surface of the heat sink 121 and protrudes from a side surface of the sealing resin 130. The lead 122 is inclined toward the wiring board 110 due to a bending process. The lead 122 is subjected to the bending process such that a distal end portion that protrudes without being covered by the sealing resin 130 is located at a position for serving as an external terminal of the electronic apparatus 100. An upper surface of the distal end portion of the lead 122, which protrudes from the sealing resin 130, and an upper surface of the wiring layer 113 that is exposed from the sealing resin 130 are located on the same plane. A thickness of the lead 122 is smaller than a thickness of the heat sink 121.

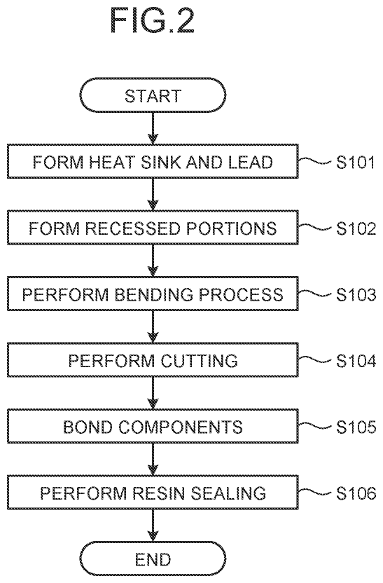

A method of manufacturing the electronic apparatus 100 configured as described above will be described below with reference to FIG. 2. FIG. 2 is a flowchart illustrating an example of the method of manufacturing the electronic apparatus 100 according to one embodiment.

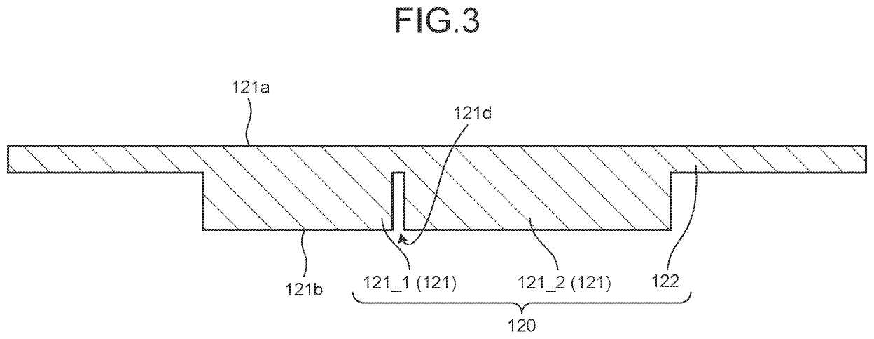

First, the heat sink 121 and the lead 122 are formed by performing pressing and rolling on a metal plate that serves as a base material of the lead frame 120 (Step S101). Specifically, as illustrated in FIG. 3 for example, the heat sink 121 and the lead 122 are formed from the metal plate. FIG. 3 is a diagram illustrating a specific example of a heat sink and lead formation process. As the metal plate, a metal plate that is made of copper or a copper alloy and that has a thickness of about 0.5 μm to 5.0 μm may be used, for example. The lead 122 is formed so as to be thinner than the heat sink 121. When the heat sink 121 and the lead 122 are formed from the metal plate, the upper surface 121a of the heat sink 121 and an upper surface of the lead 122 are located on the same plane. Further, at the same time as formation of the heat sink 121 and the lead 122, a groove portion 121d is formed in the lower surface 121b of the heat sink 121. The groove portion 121d is formed in accordance with the position of the slit 121c. The heat sink 121 is divided into the two regions 121_1 and 121_2 by the groove portion 121d.

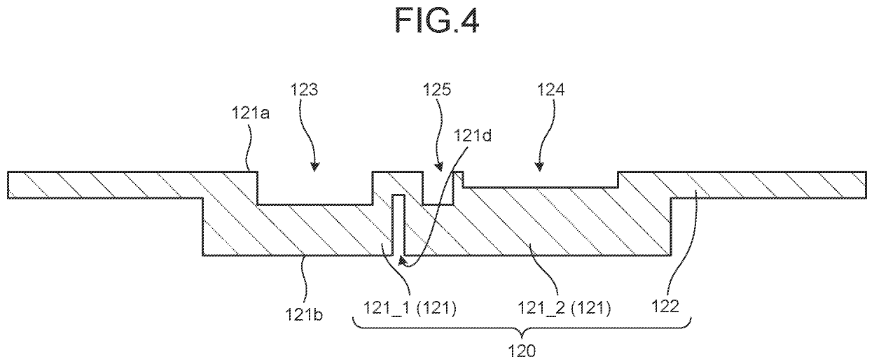

Furthermore, the recessed portions are formed in the upper surface 121a of the heat sink 121 (Step S102). Specifically, as illustrated in FIG. 4 for example, the recessed portions 123 to 125 are formed in the upper surface 121a of the heat sink 121 by, for example, etching. FIG. 4 is a diagram illustrating a specific example of a recessed portion formation process. The recessed portion 123 is formed in the upper surface 121a at the position corresponding to the electronic component 101. The recessed portion 124 is formed in the upper surface 121a at the position corresponding to the electronic component 102. The recessed portion 125 is formed in the upper surface 121a at the position corresponding to the conductive member 103. Moreover, in the recessed portions 123 to 125, etching is performed to obtain different depths corresponding to the respective thicknesses of the electronic components 101 and 102 and the conductive member 103, and the bottom surfaces with different depths from the upper surface 121a of the heat sink 121 are formed.

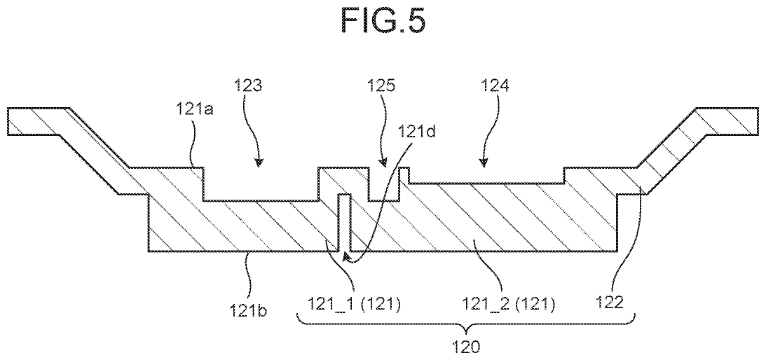

After the recessed portions 123 to 125 in the heat sink 121 are formed, the lead 122 is subjected to the bending process (Step S103). Specifically, as illustrated in FIG. 5 for example, the lead 122 is subjected to the bending process such that the distal end portion is located at a position for serving as an external terminal of the electronic apparatus 100. FIG. 5 is a diagram illustrating a specific example of the lead bending process. The position for serving as an external terminal of the electronic apparatus 100 is, for example, a position on the same plane as the upper surface of the wiring layer 113 that is exposed from the sealing resin 130.

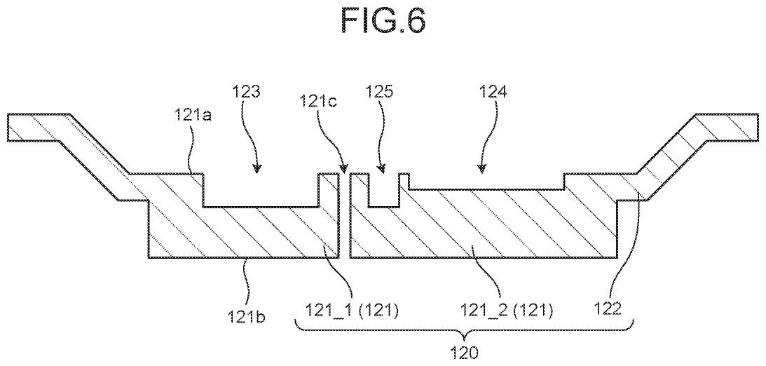

Subsequently, the heat sink 121 is cut by, for example, a dicer or a slicer (Step S104), and divided into the two regions 121_1 and 121_2. Specifically, the heat sink 121 is cut at a position that passes through the groove portion 121d, so that as illustrated in FIG. 6 for example, the heat sink 121 in which the slit 121c is formed at the position of the groove portion 121d and which includes the two regions 121_1 and 121_2 that are separated from each other is obtained. FIG. 6 is a diagram illustrating a specific example of a cutting process. Through the processes as described above, the lead frame 120 that forms a lower layer of the electronic apparatus 100 is completed.

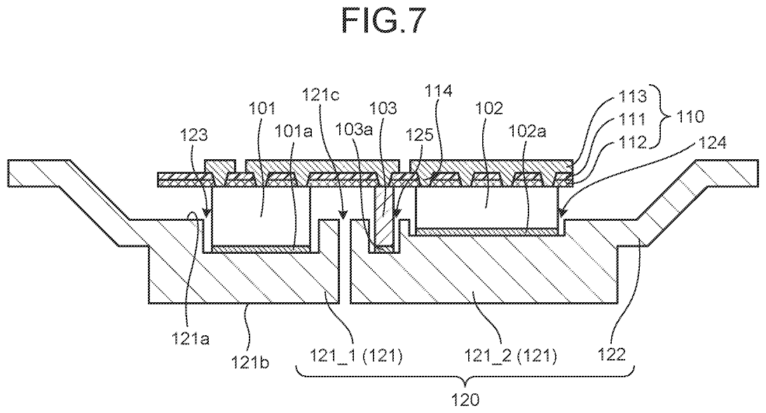

After the lead frame 120 is completed, each of the electronic components 101 and 102 and the conductive member 103 that are mounted on the wiring board 110 is bonded to the lead frame 120 (Step S105). Specifically, the electronic component 101 is housed in the recessed portion 123 of the heat sink 121 and is bonded to the bottom surface of the recessed portion 123 via the conductive bonding material 101a, such as solder paste, for example. Further, the electronic component 102 is housed in the recessed portion 124 of the heat sink 121 and is bonded to the bottom surface of the recessed portion 124 via the conductive bonding material 102a, such as solder paste, for example. Furthermore, the recessed portion 125 of the heat sink 121 is housed in the conductive member 103 and is bonded to the bottom surface of the recessed portion 125 via the conductive bonding material 103a, such as solder paste, for example. Consequently, as illustrated in FIG. 7 for example, an intermediate structure in which the wiring board 110 and the lead frame 120 sandwich the electronic components 101 and 102 and the conductive member 103 is formed. FIG. 7 is a diagram illustrating a specific example of a component bonding process.

The intermediate structure is sealed with resin by, for example, transfer molding (Step S106).

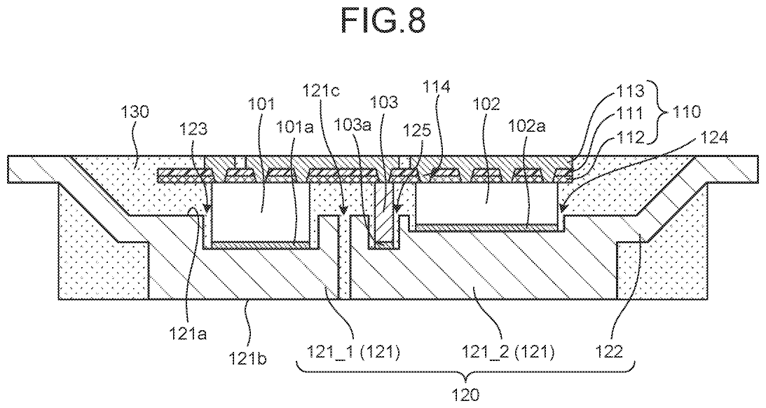

Specifically, the intermediate structure is set in a cavity of a mold, the uncured sealing resin 130 is injected from a plunger to the cavity, and thereafter the sealing resin 130 is heated and cured. Consequently, as illustrated in FIG. 8 for example, spaces around the wiring board 110, the lead frame 120, the electronic components 101 and 102, and the conductive member 103 are filled with the sealing resin 130, and the wiring board 110, the lead frame 120, the electronic components 101 and 102, and the conductive member 103 are sealed. FIG. 8 is a diagram illustrating a specific example of a resin sealing process. Even when the electronic components 101 and 102 are sealed, heat generated by the electronic components is transferred to the heat sink 121 that has a relatively large area, and dissipated from the lower surface 121b of the heat sink 121 that is exposed from the sealing resin 130. As a result, it is possible to improve heat dissipation efficiency of the electronic apparatus 100. Further, the wiring board 110 is sealed, so that the upper surface of the insulating base material 111 and the lower surface of the adhesive layer 112 are covered by the sealing resin 130. Therefore, it is possible to improve rigidity of the wiring board 110.

Thereafter, the lower surface 121b of the heat sink 121 that is exposed from the sealing resin 130 is covered by the adhesive layer 140, so that the electronic apparatus 100 is completed.

### Modification

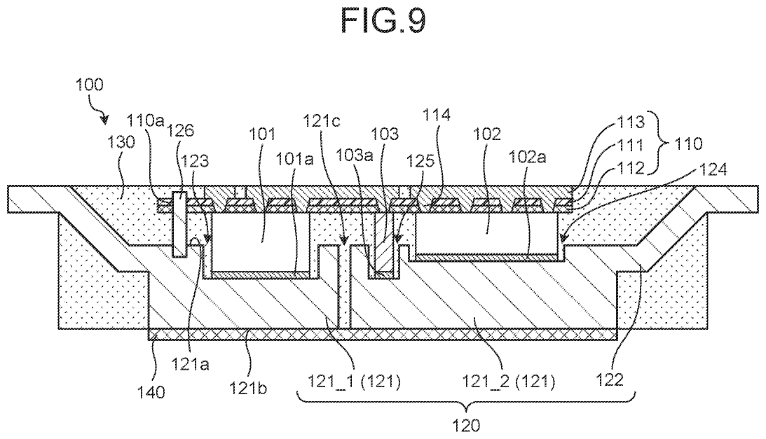

FIG. 9 is a schematic cross-sectional view illustrating a configuration of the electronic apparatus 100 according to a modification of the embodiment. Meanwhile, in the modification, the same components as those of the embodiment will be denoted by the same reference symbols, and repeated explanation will be omitted.

As illustrated in FIG. 9, in the modification, a guide pin 126 is arranged on the upper surface 121a of the heat sink 121. The guide pin 126 is arranged on the upper surface 121a of the heat sink 121 so as to protrude from a position that does not overlap with the electronic components 101 and 102 and the conductive member 103 in plan view. The guide pin 126 is longer than a separation distance between the upper surface 121a of the heat sink 121 and the lower surface of the wiring board 110.

Furthermore, an insertion hole 110a in which the guide pin 126 is inserted is arranged on the wiring board 110. The insertion hole 110a is a through hole that penetrates through the insulating base material 111 and the adhesive layer 112 of the wiring board 110.

The guide pin 126 is inserted in the insertion hole 110a, so that when the electronic components 101 and 102 and the like that are mounted on the wiring board 110 are bonded to the lead frame 120, it is possible to prevent positional deviation of the wiring board 110 with respect to the lead frame 120. With this configuration, it is possible to perform positional alignment between the lead frame 120 and the electronic components 101 and 102 or the like with high accuracy.

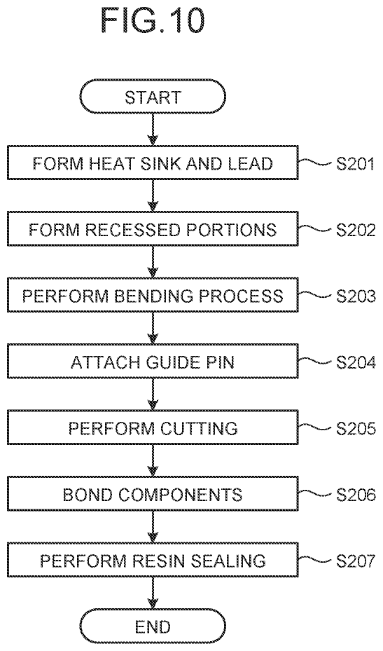

A method of manufacturing the electronic apparatus 100 according to the modification of the embodiment will be described below with reference to FIG. 10. FIG. 10 is a flowchart illustrating an example of the flow of the method of manufacturing the electronic apparatus 100 according to the modification of the embodiment.

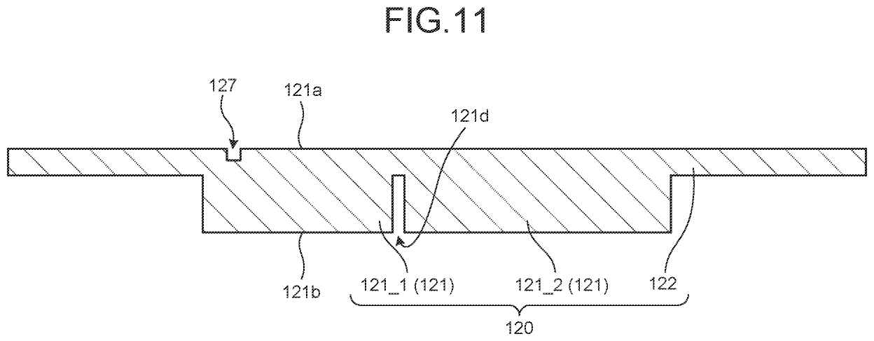

First, the heat sink 121 and the lead 122 are formed by performing pressing and rolling on a metal plate that serves as a base material of the lead frame 120 (Step S201). Specifically, as illustrated in FIG. 11 for example, the heat sink 121 and the lead 122 are formed from the metal plate. FIG. 11 is a diagram illustrating a specific example of a heat sink and lead formation process. At the time as formation of the heat sink 121 and the lead 122 from the metal plate, the groove portion 121d is formed in the lower surface 121b of the heat sink 121. Furthermore, at the same time as formation of the heat sink 121 and the lead 122 from the metal plate, a pin recessed portion 127 is formed in the upper surface 121a of the heat sink 121. The pin recessed portion 127 is formed at an attachment target position of the guide pin 126.

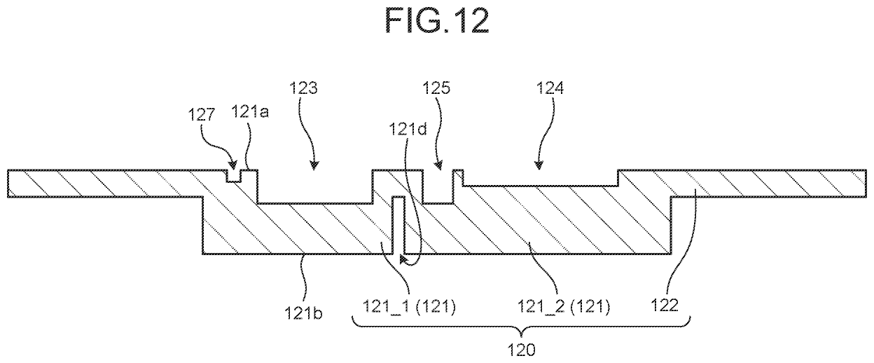

Furthermore, the recessed portions are formed in the upper surface 121a of the heat sink 121 (Step S202). Specifically, as illustrated in FIG. 12 for example, the recessed portions 123 to 125 are formed in the upper surface 121a of the heat sink 121 by, for example, etching. FIG. 12 is a diagram illustrating a specific example of a recessed portion formation process.

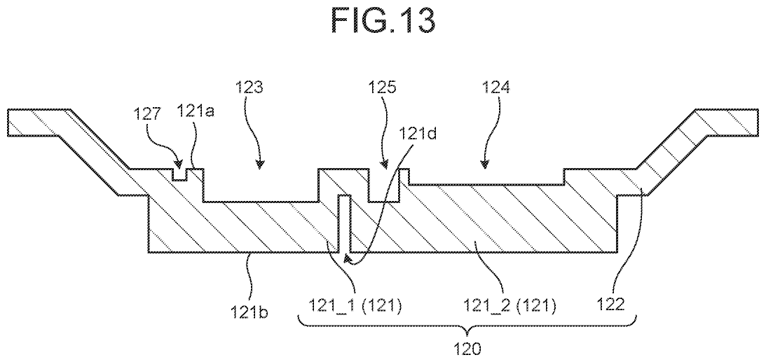

After the recessed portions 123 to 125 in the heat sink 121 are formed, the lead 122 is subjected to the bending process (Step S203). Specifically, as illustrated in FIG. 13 for example, the lead 122 is subjected to the bending process such that the distal end portion is located at a position for serving as an external terminal of the electronic apparatus 100. FIG. 13 is a diagram illustrating a specific example of the lead bending process.

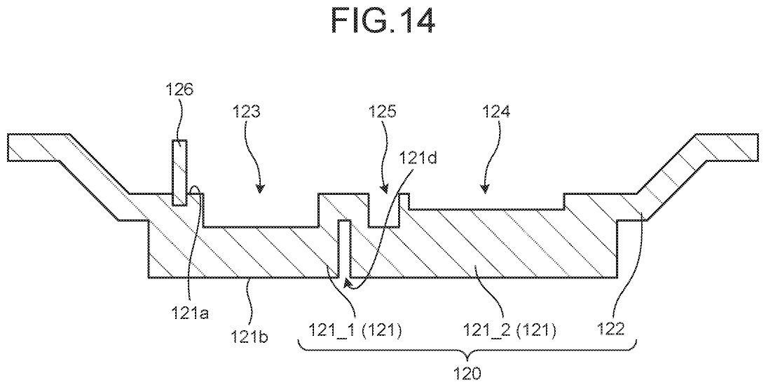

Subsequently, the guide pin 126 is attached to the pin recessed portion 127 of the heat sink 121 (Step S204). Specifically, the guide pin 126 is attached to the pin recessed portion 127 by press-fitting. Therefore, as illustrated in FIG. 14 for example, the guide pin 126 is arranged so as to stand from the upper surface 121a of the heat sink 121. FIG. 14 is a diagram illustrating a specific example of a guide pin attachment process.

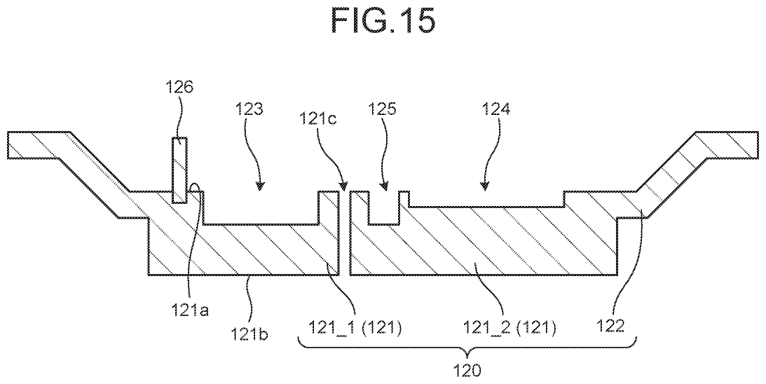

Subsequently, the heat sink 121 is cut by, for example, a dicer or a slicer (Step S205), and divided into the two regions 121_1 and 121_2. Specifically, the heat sink 121 is cut at a position that passes through the groove portion 121d, so that as illustrated in FIG. 15 for example, the heat sink 121 in which the slit 121c is formed at the position of the groove portion 121d and which includes the two regions 121_1 and 121_2 that are separated from each other is obtained. FIG. 15 is a diagram illustrating a specific example of a cutting process. Through the process as described above, the lead frame 120 that forms a lower layer of the electronic apparatus 100 is completed.

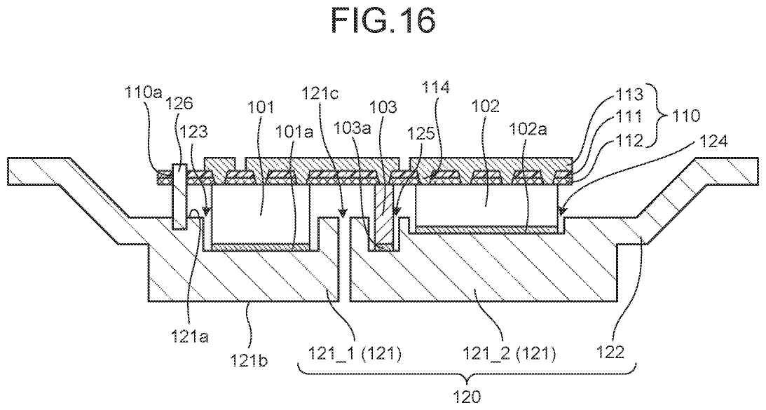

After the lead frame 120 is completed, each of the electronic components 101 and 102 and the conductive member 103 that are mounted on the wiring board 110 is bonded to the lead frame 120 (Step S206). Specifically, the electronic component 101 is housed in the recessed portion 123 of the heat sink 121 and is bonded to the bottom surface of the recessed portion 123 via the conductive bonding material 101a, such as solder paste, for example. Further, the electronic component 102 is housed in the recessed portion 124 of the heat sink 121 and is bonded to the bottom surface of the recessed portion 124 via the conductive bonding material 102a, such as solder paste, for example. Furthermore, the recessed portion 125 of the heat sink 121 is housed in the conductive member 103 and is bonded to the bottom surface of the recessed portion 125 via the conductive bonding material 103a, such as solder paste, for example. Consequently, as illustrated in FIG. 16 for example, an intermediate structure in which the wiring board 110 and the lead frame 120 sandwich the electronic components 101 and 102 and the conductive member 103 is formed. FIG. 16 is a diagram illustrating a specific example of a component bonding process. When the electronic components 101 and 102 and the conductive member 103 are bonded to the lead frame 120, the guide pin 126 is inserted in the insertion hole 110a of the wiring board 110, so that it is possible to prevent positional deviation of the wiring board 110 with respect to the lead frame 120. As a result, it is possible to perform positional alignment between the lead frame 120 and the electronic components 101 and 102 and the like.

The intermediate structure is sealed with resin by, for example, transfer molding (Step S207).

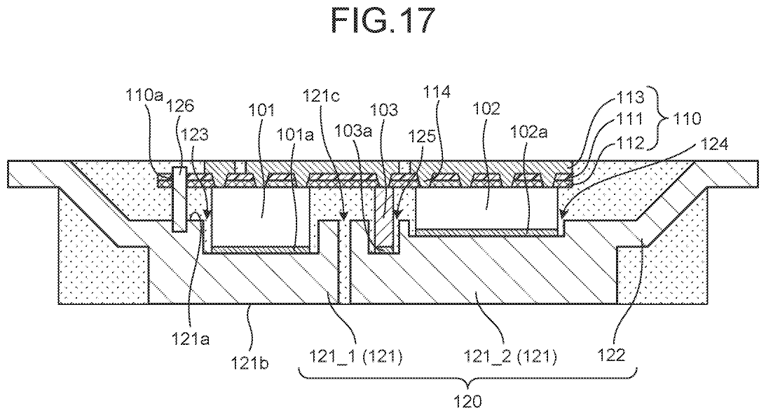

Specifically, the intermediate structure is set in a cavity of a mold, the uncured sealing resin 130 is injected from a plunger to the cavity, and thereafter the sealing resin 130 is heated and cured. Consequently, as illustrated in FIG. 17 for example, the wiring board 110, the lead frame 120, spaces around the wiring board 110, the lead frame 120, the electronic components 101 and 102, and the conductive member 103 are filled with the sealing resin 130, and the wiring board 110, the lead frame 120, the electronic components 101 and 102, and the conductive member 103 are sealed. FIG. 17 is a diagram illustrating a specific example of a resin sealing process. Even when the electronic components 101 and 102 are sealed, heat generated by the electronic components is transferred to the heat sink 121 that has a relatively large area, and dissipated from the lower surface 121b of the heat sink 121 that is exposed from the sealing resin 130. As a result, it is possible to improve heat dissipation efficiency of the electronic apparatus 100.

Thereafter, the lower surface 121b of the heat sink 121 that is exposed from the sealing resin 130 is covered by the adhesive layer 140, so that the electronic apparatus 100 is completed.

As described above, an electronic apparatus (for example, the electronic apparatus 100) according to one embodiment includes a lead frame (for example, the lead frame 120), a wiring board (for example, the wiring board 110), and sealing resin (for example, the sealing resin 130). The lead frame is made of metal. The wiring board is configured such that an electronic component (for example, the electronic components 101 and 102) is mounted and the electronic component is boded to the lead frame. The sealing resin seals the lead frame, the electronic component, and the wiring board. The lead frame includes a first surface (for example, the upper surface 121a) that is bonded to the electronic component and a second surface (for example, the lower surface 121b) that is located opposite to the first surface and that is exposed from the sealing resin. With this configuration, according to the electronic apparatus of one embodiment, it is possible to improve heat dissipation efficiency.

Furthermore, the wiring board includes an insulating base material (for example, the insulating base material 111), a wiring layer (for example, the wiring layer 113) that is formed on a first surface (for example, the upper surface) of the insulating base material, and an adhesive layer (for example, the adhesive layer 112) that is laminated on a second surface (for example, the lower surface) of the insulating base material on an opposite side of the first surface and that includes a second surface to which the electronic component is bonded. The first surface of the insulating base material and the second surface of the adhesive layer are covered by the sealing resin. With this configuration, according to the electronic apparatus of one embodiment, it is possible to improve rigidity of the wiring board.

Moreover, the lead frame may include a heat sink (for example, the heat sink 121) that has a first surface that is bonded to the electronic component, and a lead (for example, the lead 122) that is connected to a side surface located adjacent to the first surface and a second surface of the heat sink and that protrudes from the sealing resin. With this configuration, according to the electronic apparatus of one embodiment, it is possible to dissipate heat that is generated by the electronic component from the heat sink and the lead, so that it is possible to further improve the heat dissipation efficiency.

Furthermore, the first surface of the lead frame may include a recessed portion (for example, the recessed portions 123 and 124) at a position corresponding to the electronic component, and the electronic component may be housed in the recessed portion and bonded to a bottom surface of the recessed portion. With this configuration, according to the electronic apparatus of one embodiment, it is possible to reduce an interval between the heat sink and the wiring board, so that it is possible to reduce a thickness of the electronic apparatus.

Moreover, it may be possible to mount, on the wiring board, a plurality of electronic components (for example, the electronic components 101 and 102) with different thicknesses. The first surface of the lead frame may include a plurality of recessed portions (for example, the recessed portions 123 and 124) corresponding to the respective electronic components. The plurality of recessed portions may have bottom surfaces located at different depths from the first surface in accordance with the thicknesses of the respective electronic components. With this configuration, according to the electronic apparatus of one embodiment, even when the plurality of electronic components have different thicknesses, it is possible to promote reduction of the thickness of the electronic apparatus.

Furthermore, the lead frame may include a plurality of regions (for example, the regions 121_1 and 121_2) that are separated from each other. The plurality of recessed portions may be formed in the plurality of regions in a distributed manner and house the corresponding electronic components. With this configuration, according to the electronic apparatus of one embodiment, it is possible to independently dissipate heat that is generated by the electronic components in the plurality of regions.

Moreover, the first surface of the lead frame may include a guide pin (for example, the guide pin 126) that stands from a position that does not overlap with the electronic component in plan view. The wiring board may include an insertion hole (for example, the insertion hole 110a) in which the guide pin is inserted. With this configuration, according to the electronic apparatus of one embodiment, it is possible to align positions of the lead frame and the electronic component with high accuracy.

According to one aspect of the electronic apparatus disclosed in the present application, it is possible to improve heat dissipation efficiency.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic apparatus comprising:
a lead frame that is made of metal;
a wiring board that mounts an electronic component bonded to the lead frame; and
sealing resin that seals the lead frame, the electronic component, and the wiring board, wherein
the lead frame includes
a first surface that is bonded to the electronic component and that is covered by the sealing resin, and
a second surface that is located opposite to the first surface and that is exposed from the sealing resin,
the wiring board includes
an insulating base material,
a wiring layer that is formed on a first surface of the insulating base material, and
an adhesive layer that is laminated on a second surface of the insulating base material on an opposite side of the first surface and that includes a second surface to which the electronic component is bonded, and
the first surface of the insulating base material and the second surface of the adhesive layer are covered by the sealing resin.

2. The electronic apparatus according to claim 1, wherein the lead frame includes
a heat sink that has the first surface that is bonded to the electronic component, and
a lead that that is connected to a side surface located adjacent to the first surface and the second surface of the heat sink and that protrudes from the sealing resin.

3. The electronic apparatus according to claim 1, wherein
the first surface of the lead frame includes a recessed portion at a position corresponding to the electronic component, and
the electronic component is housed in the recessed portion and bonded to a bottom surface of the recessed portion.

4. The electronic apparatus according to claim 3, wherein
the wiring board mounts a plurality of the electronic components with different thicknesses,
the first surface of the lead frame includes a plurality of the recessed portions at positions corresponding to the plurality of the electronic components respectively, and
the plurality of the recessed portions have bottom surfaces located at different depths from the first surface in accordance with the thicknesses of the plurality of the electronic components respectively.

5. The electronic apparatus according to claim 4, wherein
the lead frame includes a plurality of regions that are separated from each other, and
the plurality of the recessed portions are formed in the plurality of regions in a distributed manner and house the corresponding electronic components respectively.

6. The electronic apparatus according to claim 1, wherein
the first surface of the lead frame includes a guide pin that stands from a position that does not overlap with the electronic component in plan view, and
the wiring board includes an insertion hole in which the guide pin is inserted.

7. The electronic apparatus according to claim 1, wherein a first surface of the wiring layer opposite to the insulating base material is exposed from the sealing resin.
